(19) United States
(12) Patent Application Publication
(10) Pub. No.: US 2009/0085672 A1
(43) Pub. Date: Apr. 2, 2009

(54) FREQUENCY SYNTHESIZER

(76) Inventors: Takeshi Ikeda, Tokyo (JP); Hiroshi Miyagi, Kanagawa (JP)

Correspondence Address: CONNOLLY BOVE LODGE & HUTZ LLP, 1875 EYE STREET, N.W., SUITE 1100, WASHINGTON, DC, 20006, US

(21) Appl. No.: 12/093,742

(22) PCT Filed: Jul. 12, 2006
(86) PCT No.: PCT/JP2006/314210

§ 371 Date: May 15, 2008

(30) Foreign Application Priority Data
Nov. 18, 2005 (JP) 2005-333677

(51) Int. Cl. H03L 7/06

(52) U.S. Cl. 331/17

(57) ABSTRACT

By performing rough adjustment of a local oscillation frequency by a first lock loop using an up/down counter (5) and micro adjustment of the local oscillation frequency by a second lock loop using an S/H circuit (11), it is possible to eliminate the need of operation of charging and pumping a capacitor according to a phase difference and to omit an LPF using a large-scale capacitor from the frequency synthesizer. Moreover, by performing micro adjustment using the S/H circuit (11), it is possible to accurately lock the local oscillation frequency and eliminate the need of increasing the bit quantity of the up/down counter (5) to increase the control accuracy of the frequency to be locked. Thus, it is possible to rapidly lock the local oscillation frequency to a desired frequency.

### TECHNICAL FIELD

The present invention relates to a frequency synthesizer, and in particular, preferably relates to a frequency synthesizer using a phase locked loop.

### BACKGROUND ART

In general, a frequency synthesizer using a phase locked loop (PLL) is used in the wireless communication equipment. FIG. 1 shows a general configuration of the frequency synthesizer using the PLL. As shown in FIG. 1, the frequency synthesizer is configured to be provided with a reference generator 101, a programmable counter (PC) 102, a phase comparator 103, a charge pump circuit 104, a low-pass filter (LPF) 105, and a voltage-controlled oscillator (VCO) 106.

The reference generator 101 generates a reference signal of a reference frequency. The PC 102 divides a frequency outputted from the VCO 106 at a specified frequency dividing ratio, and outputs the result as a comparison signal of a variable frequency to the phase comparator 103. The phase comparator 103 detects a phase difference between a reference signal outputted from the reference generator 101 and a comparison signal outputted from the PC 102, and outputs a control signal of the logic “L” or “H” depending on the detection result from an “Up” terminal and a “Down” terminal.

The charge pump circuit 104 performs a charge operation or a pump operation of a capacitor constituting the LPF 105 based on the control signals outputted from the “Up” terminal and the “Down” terminal of the phase comparator 103. FIG. 2 shows an example of a configuration of the charge pump circuit 104. As shown in FIG. 2, the charge pump circuit 104 is provided with a first switch 104a connected between the power supply and the LPF 105 and a second switch 104b connected between the ground and the LPF 105, and one of the switches is turned on based on the control signal outputted from the “Up” terminal and the “Down” terminal of the phase comparator 103.

More specifically, when the phase of a comparison signal lags a phase of the reference signal, a control signal of logic “H” having a pulse width corresponding to the phase difference is outputted from the “Up” terminal of the phase comparator 103. At this time, the control signal of logic “L” is outputted from the “Down” terminal of the phase comparator 103. As a result, the first switch 104a of the charge pump circuit 104 is turned on, and an electric charge is supplied (charged) to the capacitor of the LPF 105.

On the contrary, when the phase of the comparison signal leads the phase of the reference signal, a control signal of logic “H” having a pulse width corresponding to the phase difference is outputted from the “Down” terminal of the phase comparator 103. At this time, the control signal of logic “L” is outputted from the “Up” terminal of the phase comparator 103. As a result, the second switch 104b of the charge pump circuit 104 is turned on, and an electric charge is discharged (pumped) from the capacitor of the LPF 105.

The LPF 105 is configured to be provided with a capacitor and a resistor, and outputs a signal to the VCO 106 by removing a high-frequency component from the signal outputted from the charge pump circuit 104. The VCO 106 oscillates at a frequency proportional to the voltage of a signal outputted from the LPF 105 and outputs the signal as a local oscillation signal to outside the frequency synthesizer as well as to the PC 102.

Here, when the phase of a comparison signal lags the phase of a reference signal and the charge pump circuit 104 changes an electric charge to the LPF 105, an oscillator frequency of the VCO 106 rises. The local oscillation signal outputted from the VCO 106 is outputted to the PC 102. At this time, the frequency of the comparison signal outputted from the PC 102 rises and the phase difference to the reference signal becomes small. As a result, the frequency of a local oscillation signal outputted from the VCO 106 becomes close to a desired frequency proportional to a frequency of the reference signal.

On the contrary, when the phase of the comparison signal leads the phase of the reference signal and the charge pump circuit 104 discharges an electric charge of the LPF 105, the oscillator frequency of the VCO 106 falls. The local oscillation signal outputted from the VCO 106 is outputted to the PC 102. At this time, the frequency of a comparison signal outputted from the PC 102 falls, and the phase difference to the reference signal becomes small. As a result, the frequency of a local oscillation signal outputted from the VCO 106 becomes close to a desired frequency proportional to a frequency of the reference signal.

Accordingly, the frequency synthesizer operates such that regardless whether the frequency of a comparison signal (frequency proportional to an output frequency of the VCO 106) is higher or lower than the frequency of a reference signal, finally the frequency of the comparison signal becomes close to the frequency of the reference signal. Thereby, the oscillator frequency of the VCO 106 is locked to a fixed frequency. In this locked state, control signals outputted from the phase comparator 103, both at the “Up” terminal and the “Down” terminal are logic “L” signals.

According to the frequency synthesizer configured as above, the lower the frequency to be compared by the phase comparator 103, the larger capacity is required for a capacitor constituting the LPF 105. For this reason, there is a problem in that it is difficult to integrate the LPF 105 into a semiconductor chip. In view of this problem, a technique has been provided which configures a PLL circuit using an up/down counter and a D/A converter (for example, see Patent Document 1). This technique can omit the LPF using a large-capacity capacitor from the PLL circuit.

Patent Document 1: Japanese Patent Laid-Open No. 9-152561

### DISCLOSURE OF THE INVENTION

However, when the PLL circuit using the up/down counter and the D/A converter is configured, there is a problem in that the number of bits of the counter limits the control accuracy of the frequency to be locked and the processing speed. More specifically, when the D/A converter is used to enter a stationary state, no response is returned during a certain period while a locked loop is in an open state. In such a non-sensing period, the oscillator frequency cannot be successfully controlled. If the number of bits of the up/down counter and the D/A converter is increased, the control accuracy can be increased, while the processing speed is decreased and the circuit scale must be larger. On the contrary, if the number of bits thereof is decreased, the processing speed can be increased, but the control accuracy is decreased.

In order to solve such a problem, the present invention has been made, and an object of the present invention is to configure a PLL circuit to be integrated in a single semiconductor chip without sacrificing the control accuracy of a frequency to be locked and the processing speed.

To solve the above problem, the present invention performs a rough adjustment on a local oscillation frequency by an up/down counter which performs a count operation based on a signal for oscillation control outputted from a phase comparator and a D/A converter which obtains a voltage value by performing a D/A conversion on a count value outputted from the up/down counter and supplying the voltage value to a local oscillation circuit. In addition, the present invention performs a micro adjustment on the local oscillation frequency by a non-stationary signal generating circuit which generates a non-stationary signal having a waveform in which the voltage value varies constantly at a fixed cycle in terms of time; a pulse generation circuit which generates a sampling pulse based on a comparison signal outputted from a variable frequency divider; and a sample hold circuit which sample-holds a voltage value of the non-stationary signal by a sampling pulse and supplies the held voltage value to the local oscillation circuit.

In addition, the other aspect of the present invention performs the most rough adjustment on a local oscillation frequency by greatly changing the capacitance value of a varactor diode constituting a local oscillation circuit by a frequency comparator which compares to see which is higher or lower between a frequency of the local oscillation signal outputted from the local oscillation circuit and a target frequency as well as compares to see which is higher or lower between frequencies corresponding to the borders of a frequency range containing the target frequency of the frequency ranges obtained by dividing the range of a oscillator frequency permitted by the local oscillation circuit by “n” (2 or more integer) and a frequency of the local oscillation signal counted by a frequency counter; and a control circuit which changes the switch selection states based on the result compared by the frequency comparator. Subsequently, as described above, the up/down counter and the D/A converter are used to perform a rough adjustment on the local oscillation frequency as well as perform a micro adjustment on the local oscillation frequency by the non-stationary wave signal generating circuit, the pulse generation circuit, and the sample hold circuit.

According to the present invention configured as above, a method is used to configure the frequency synthesizer using the up/down counter and the D/A converter and thus the method does not require an operation such as charging or pumping an electric charge to and from the capacitor depending on the phase difference between the reference signal and the comparison signal. Therefore, it is possible to omit the LPF using a large-capacity capacitor from the frequency synthesizer and to integrate the frequency synthesizer in a single semiconductor chip. In addition, according to the present invention, a rough adjustment is performed on a local oscillation frequency by the up/down counter and a micro adjustment is performed on the local oscillation frequency by the sample hold circuit. Consequently, it is not required to increase the number of bits of the up/down counter in order to increase the control accuracy of a frequency to be locked, and thus the local oscillation frequency can be locked to a desired frequency at a high speed. Additionally, a micro adjustment using the sample hold circuit can lock the local oscillation frequency with a good precision. A capacitance of several picofarads (pF) is enough for a capacitor for the sample hold circuit and thus the sample hold circuit can be easily integrated on a semiconductor chip.

### BRIEF DESCRIPTION OF THE DRAWINGS

FIG. 1 shows an example of an overall configuration of a conventional frequency synthesizer;

FIG. 2 shows an example of a configuration of a charge pump circuit;

FIG. 3 shows an example of an overall configuration of a frequency synthesizer in accordance with a first embodiment;

FIG. 4 is a waveform chart explaining that a non-stationary wave generating circuit generates a triangular wave signal from a reference signal;

FIG. 5 shows an example of a configuration of a pulse generation circuit;

FIG. 6 is a timing chart for explaining an operation of the pulse generation circuit configured as shown in FIG. 5;

FIG. 7 is a diagram for explaining an operation of the frequency synthesizer in accordance with a first embodiment; FIG. 7(a) shows an operation by a first locked loop and FIG. 7(b) shows an operation by a second locked loop;

FIG. 8 shows an example of an overall configuration of a frequency synthesizer in accordance with a second embodiment; and

FIG. 9 shows an example of dividing frequencies used by a third locked loop in accordance with the second embodiment.

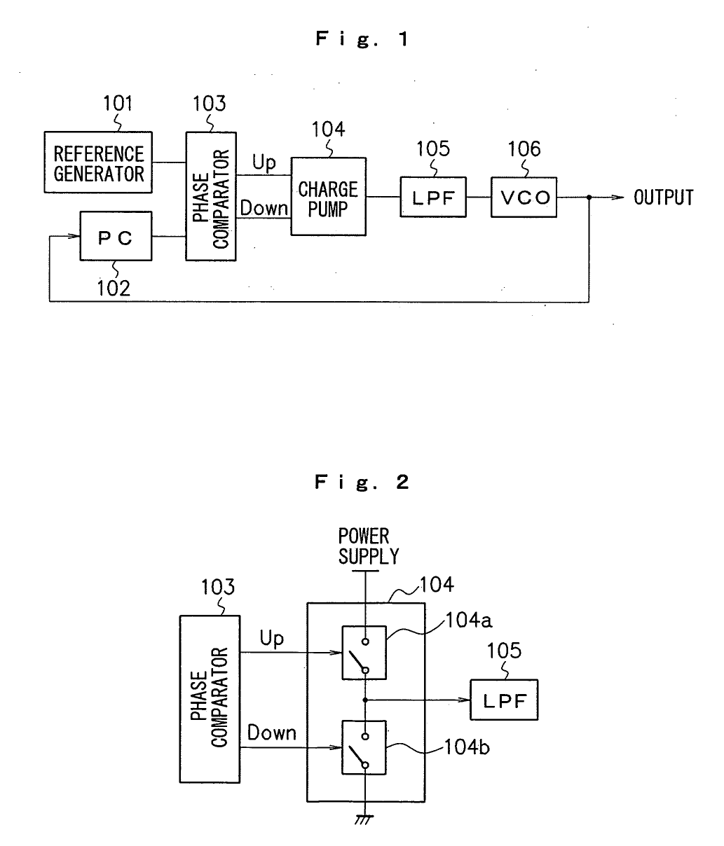

### BEST MODE FOR CARRYING OUT THE INVENTION

### First Embodiment

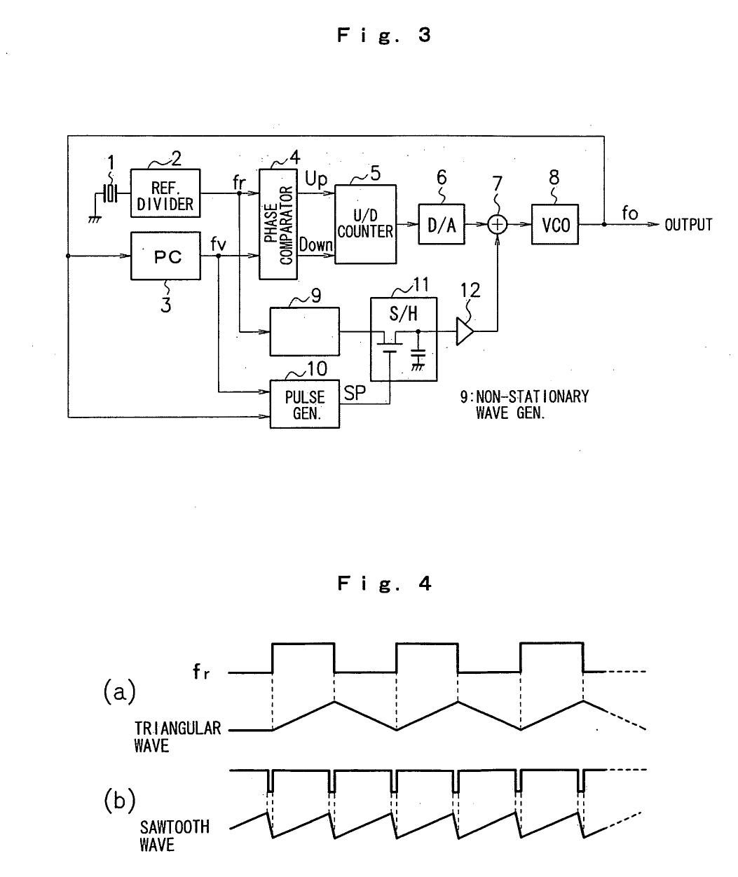

Hereinafter, an embodiment of the present invention will be described with reference to drawings. FIG. 3 shows an example of an overall configuration of a frequency synthesizer in accordance with a first embodiment. As shown in FIG. 3, the frequency synthesizer in accordance with the present embodiment is configured to be provided with a crystal oscillator circuit 1, a reference divider 2, a programmable counter (PC) 3, a phase comparator 4, an up/down counter 5, a D/A converter 6, an adder 7, a voltage-controlled oscillator (VCO) 8, a non-stationary wave generating circuit 9, a pulse generation circuit 10, a sample hold (S/H) circuit 11, and a buffer 12.

Each of these configuration elements 1 to 12 is integrated on the same semiconductor chip, for example, by a CMOS (Complementary Metal Oxide Semiconductor) process or a BiCMOS (Bipolar-CMOS) process. It should be noted that according to the present embodiment, all of these configuration elements 1 to 12 need not be integrated on a single semiconductor chip.

The crystal oscillator circuit 1 generates a signal having a predetermined frequency. The reference divider 2 divides the frequency of a signal outputted from the crystal oscillator circuit 1 at a fixed frequency dividing ratio and generates a reference signal fᵣ. The reference generator in accordance with the present invention is configured with the crystal oscillator circuit 1 and the reference divider 2. The PC 3 corresponds to the variable frequency divider of the present invention. The PC 3 divides the frequency of a local oscillation signal outputted from the VCO 8 at a specified frequency dividing ratio, and outputs the result as a comparison signal fᵥ of the variable frequency to the phase comparator 4.

The phase comparator 4 detects a phase difference between the reference signal fᵣ outputted from the reference divider 2 and the comparison signal fᵥ outputted from the PC 3, and outputs a signal for oscillation control of the VCO 8 based on the detected phase difference from the “Up” terminal and the “Down” terminal. The signal for oscillation control outputted from the “Up” terminal and the “Down” terminal is a signal of logic “L” or “H”.

In other words, when the phase of the comparison signal fᵥ lags the phase of the reference signal fᵣ, the phase comparator 4 outputs a control signal of logic “H” having a pulse width corresponding to the phase difference from the “Up” terminal. At this time, the phase comparator 4 outputs a control signal of logic “L” from the “Down” terminal. On the contrary, when the phase of the comparison signal fᵥ leads the phase of the reference signal fᵣ, the phase comparator 4 outputs a control signal of logic “H” having a pulse width corresponding to the phase difference from the “Down” terminal. At this time, the phase comparator 4 outputs a control signal of logic “L” from the “Up” terminal. Alternatively, when the phase of the comparison signal fᵥ is synchronized with the phase of the reference signal fᵣ, the phase comparator 4 outputs control signals of logic “L” from the “Up” terminal and the “Down” terminal.

The up/down counter 5 performs a count operation based on the control signals of logic “H” outputted from the “Up” terminal and the “Down” terminal of the phase comparator 4. In other words, while the control signal of logic “H” is outputted from the “Up” terminal of the phase comparator 4, the up/down counter 5 performs a count-up operation. On the contrary, while the control signal of logic “H” is outputted from the “Down” terminal of the phase comparator 4, the up/down counter 5 performs a count-down operation. It should be noted that the up/down counter 5 in accordance with the present embodiment needs not increase the number of bits thereof in order to improve the control accuracy of the oscillator frequency.

The D/A converter 6 obtains a voltage value by performing a D/A conversion on the count value outputted from the up/down counter 5 and supplies the obtained voltage value through the adder 7 to the VCO 8. The VCO 8 corresponds to the local oscillation circuit of the present invention. The VCO 8 oscillates at a frequency proportional to the voltage value supplied from the adder 7 and outputs a signal of the local oscillation frequency obtained as a result thereof as the local oscillation signal fₒ to outside the frequency synthesizer as well as to the PC 3.

The non-stationary wave generating circuit 9 corresponds to the non-stationary signal generating circuit of the present invention, and, for example, as shown in FIG. 4(a), generates a triangular wave by integrating reference signal fᵣ outputted from the reference divider 2. The triangular wave generated here is a non-stationary signal having a waveform in which the voltage value varies constantly at a fixed rate in terms of time.

It should be noted that according to the present embodiment, an example of generating a triangular wave is described, but a signal having any other waveform may be used as long as the signal has a waveform in which the voltage value varies constantly at a fixed rate in terms of time. For example, as shown in FIG. 4 (b), a sawtooth wave may be generated. In addition, according to the present embodiment, a non-stationary signal is generated by integrating the reference signal fᵣ, but the method of generating a non-stationary signal is not limited to this.

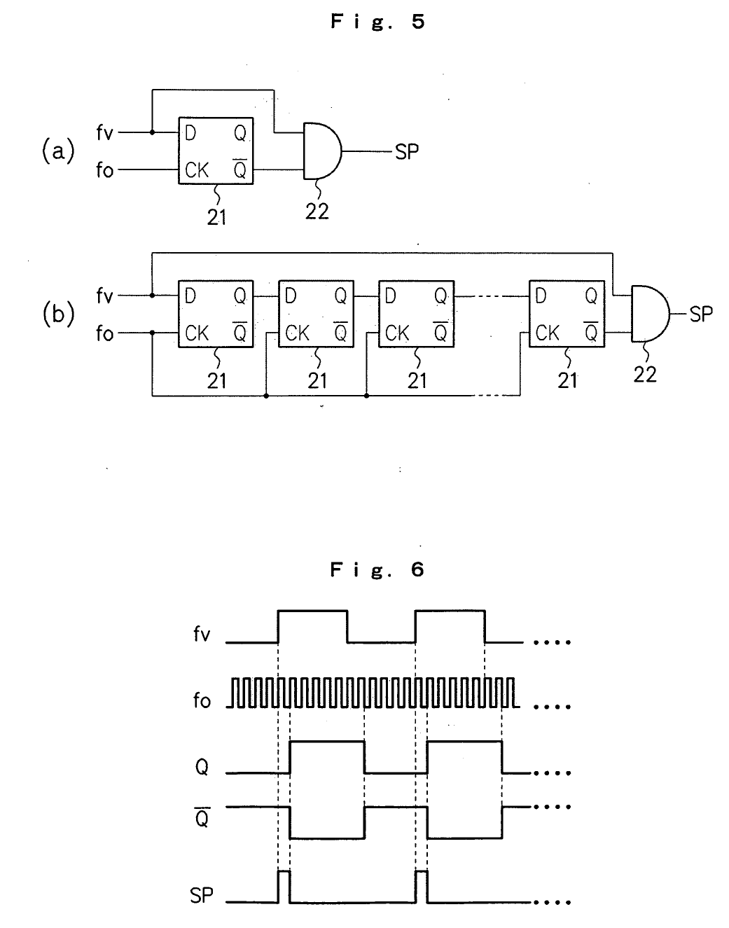

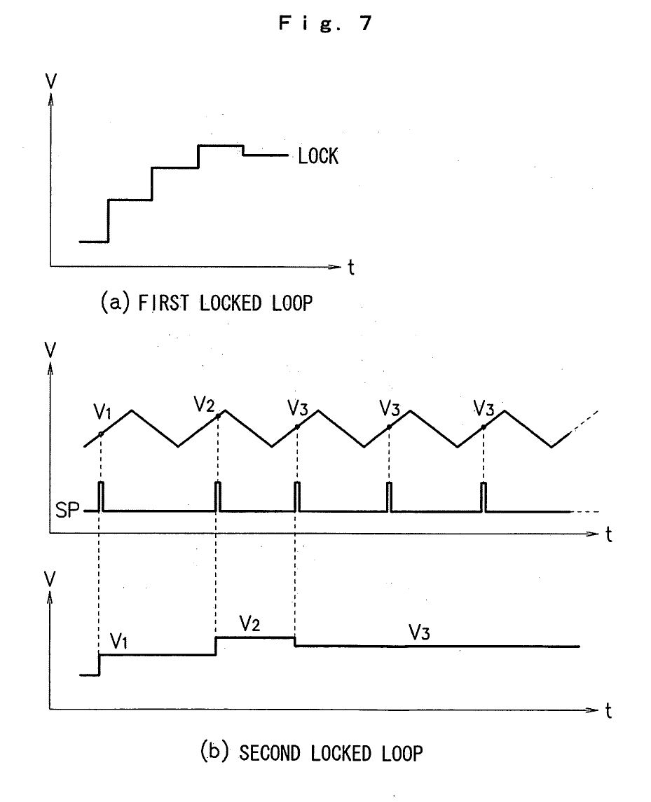

The pulse generation circuit 10 generates a sampling pulse SP for sample-holding the S/H circuit 11 based on the comparison signal fᵥ outputted from the PC 3 and the local oscillation signal fₒ outputted from the VCO 8. FIG. 5 shows an example of a configuration of the pulse generation circuit 10. FIG. 6 is a timing chart for explaining an operation of the pulse generation circuit 10 configured as configured in FIG. 5.

As shown in FIG. 5(a), the pulse generation circuit 10 is provided with, for example, a D-type flip-flop 21 and an AND circuit 22. In the D-type flip-flop 21, a comparison signal fᵥ from the PC 3 is inputted to a data input terminal D and a local oscillation signal fₒ from the VCO 8 is inputted to a clock terminal CK. As shown in FIG. 6, the local oscillation signal fₒ is shorter in cycle than the comparison signal fᵥ and this is used as an operation clock of the D-type flip-flop 21. In this configuration, the comparison signal fᵥ inputted to the data input terminal D is outputted one cycle behind the local oscillation signal fₒ from a positive output terminal Q. At the same time, an inversion signal thereof is outputted from a negative output terminal Q bar. The AND circuit 22 generates an one-shot sampling pulse SP, which assumes logic “H” only once in a cycle of the local oscillation signal fₒ during the period when the comparison signal fᵥ is logic “H”, by performing a logical AND operation between the comparison signal fᵥ outputted from the PC 3 and the signal outputted from the negative output terminal Q bar of the D-type flip-flop 21.

It should be noted that here an example is described in which the local oscillation signal fₒ is used as the operation clock of the D-type flip-flop 21, but the present invention is not limited to this. Any signal other than the local oscillation signal fₒ may be used as long as the signal is synchronized with the comparison signal fᵥ and is shorter in cycle than the comparison signal fᵥ. For example, such a signal may be generated by another timing generation circuit (not shown).

Alternatively, the pulse generation circuit 10 may generate a sampling pulse SP based on the comparison signal fᵥ outputted from the PC 3 and a signal (e.g., a signal outputted from a 1/n prescaler (n is an integer such as 16, 32, and 64) provided in the PC 3) in mid flow in which the PC 3 is performing a frequency division on the local oscillation signal fₒ outputted from the VCO 8. The larger the frequency dividing ratio of the PC 3, the larger the duty of the sampling pulse SP, and the pulse width becomes extremely thin like a beard. Consequently, the pulse signal may be invisible. The pulse width of the sampling pulse SP may be large to some extent by using an output of the prescaler at a stage of a small frequency dividing ratio.

Alternatively, instead of using a signal in mid flow of frequency division by the PC 3, a plurality of D-type flip-flops 21 may be cascade-connected as shown in FIG. 5(b). In this way, the pulse width of the sampling pulse SP may be large to some extent. In the case of using a signal in mid flow of a frequency division by the PC 3, the pulse width of the sampling pulse SP may change depending on the frequency dividing ratio. Therefore, a configuration of multistage-connected D-type flip-flops 21 is preferable in terms of stabilizing the pulse width. It should be noted that although the pulse width of the sampling pulse SP may change depending on the frequency dividing ratio, the amount of changes of the pulse width may be ignored since the frequency range is narrow.

The S/H circuit 11 sample-holds the voltage value of a triangular wave signal generated by the non-stationary wave generating circuit 9, by the sampling pulse SP generated by the pulse generation circuit 10 and supplies the held voltage value through the buffer 12 and the adder 7 to the VCO 8. The adder 7 adds a voltage value supplied from the D/A converter 6 and a voltage value supplied through buffer 12 from the S/H circuit 11 and supplies the added voltage value to the VCO 8.

According to the above frequency synthesizer, a first locked loop is formed with a loop connecting the phase comparator 4, the up/down counter 5, and the D/A converter 6. In addition, a second locked loop is formed with a loop connecting the non-stationary wave generating circuit 9, the pulse generation circuit 10, and the S/H circuit 11.

Hereinafter, the operation of the frequency synthesizer in accordance with the first embodiment configured as shown above will be described. FIG. 7 is a diagram for explaining an operation of the frequency synthesizer in accordance with the first embodiment; FIG. 7(a) shows an operation by the first locked loop and FIG. 7(b) shows an operation by the second locked loop.

In the first locked loop, the phase comparator 4 detects the phase difference between a reference signal fᵣ outputted from the reference divider 2 and a comparison signal fᵥ outputted from the PC 3. When the phase of the comparison signal fᵥ lags the phase of the reference signal fᵣ, a control signal of logic “H” having a pulse width corresponding to the phase difference is outputted from the “Up” terminal of the phase comparator 4. At this time, a control signal of logic “L” is outputted from the “Down” terminal of the phase comparator 4.

The control signal of logic “H” outputted from the “Up” terminal and the control signal of logic “L” outputted from the “Down” terminal of the phase comparator 4 are inputted to the up/down counter 5. The up/down counter 5 performs a count up operation in synchronism with the control signal of logic “H” inputted from the “Up” terminal of the phase comparator 4. The D/A converter 6 performs a D/A conversion on the counted-up value and the obtained voltage value is outputted through the adder 7 to the VCO 8.

When the voltage value outputted from the D/A converter 6 rises by such a count up operation of the up/down counter 5, the oscillator frequency of the VCO 8 rises accordingly. Consequently, the frequency of the local oscillation signal fₒ fed back from the VCO 8 to the PC 3 rises, and the frequency of the comparison signal fᵥ obtained by dividing this frequency also rises. Then, the frequency of the comparison signal fᵥ which was lower than the frequency of the reference signal fᵣ becomes close to the frequency of the reference signal fᵣ. As a result, the frequency of a local oscillation signal fₒ outputted from the VCO 8 becomes close to a desired frequency proportional to the frequency of the reference signal fᵣ.

On the contrary, when the phase of the comparison signal fᵥ leads the phase of the reference signal fᵣ, the control signal of logic “H” having a pulse width corresponding to the phase difference is outputted from the “Down” terminal of the phase comparator 4. At this time, the control signal of logic “L” is outputted from the “Up” terminal of the phase comparator 4.

The control signal of logic “L” outputted from the “Up” terminal of the phase comparator 4 and the control signal of logic “H” outputted from the “Down” terminal of the phase comparator 4 are inputted to the up/down counter 5. The up/down counter 5 performs a count down operation in synchronism with the control signal of logic “H” inputted from the “Down” terminal of the phase comparator 4. Then, the D/A converter 6 performs a D/A conversion on the counted-down value and the obtained value is outputted through the adder 7 to the VCO 8.

When the voltage value outputted from the D/A converter 6 falls by such a count down operation of the up/down counter 5, the oscillator frequency of the VCO 8 falls accordingly. Consequently, the frequency of the local oscillation signal fₒ fed back from the VCO 8 to the PC 3 falls, and the frequency of the comparison signal fᵥ obtained by dividing this frequency also falls. Then, the frequency of the comparison signal fᵥ which was higher than the frequency of the reference signal fᵣ becomes close to the frequency of the reference signal fᵣ. As a result, the frequency of a local oscillation signal fₒ outputted from the VCO 8 becomes close to a desired frequency proportional to the frequency of the reference signal fᵣ.

Accordingly, as shown in FIG. 7(a), the frequency synthesizer operates such that regardless whether the frequency of a comparison signal fᵥ is higher or lower than the frequency of the reference signal fᵣ, the frequency of the comparison signal fᵥ becomes close to the frequency of the reference signal fᵣ. Then, finally both the control signals outputted from the “Up” terminal and the “Down” terminal of the phase comparator 4 are logic “L”. Consequently, the up/down counter 5 terminates the count operation, and outputs a fixed count value.

It should be noted that the number of bits of the up/down counter 5 in accordance with the present embodiment is not so large and the frequency resolution is not very high. Consequently, the processing speed of oscillator frequency adjustment can be increased, but it is difficult to match the frequency of a comparison signal fᵥ and the frequency of the reference signal fᵣ with a good precision. According to the present embodiment, in order to match the frequency of a comparison signal fᵥ and the frequency of the reference signal fᵣ with a good precision, a micro adjustment of the oscillator frequency is performed in the second locked loop using the S/H circuit 11.

More specifically, the non-stationary wave generating circuit 9 generates a triangular wave signal by integrating a reference signal fᵣ outputted from the reference divider 2. In addition, the pulse generation circuit 10 generates a sampling pulse SP in synchronism with the comparison signal fᵥ. Then, as shown in FIG. 7(b), the S/H circuit 11 sample-holds the voltage value of a triangular wave signal generated by the non-stationary wave generating circuit 9, by the sampling pulse SP generated by the pulse generation circuit 10 and supplies the held voltage value through the buffer 12 and the adder 7 to the VCO 8.

For example, when a voltage value outputted from the buffer 12 rises by such a sample hold operation, the oscillator frequency of the VCO 8 rises accordingly. Consequently, the frequency of the local oscillation signal fₒ fed back from the VCO 8 to the PC 3 rises, and the frequency of the comparison signal fᵥ obtained by dividing this frequency also rises. Then, the frequency of the comparison signal fᵥ which was lower than the frequency of the reference signal fᵣ becomes close to the frequency of the reference signal fᵣ. As a result, the frequency of a local oscillation signal fₒ outputted from the VCO 8 becomes close to a desired frequency proportional to the frequency of the reference signal fᵣ.

On the contrary, when the voltage value outputted from the buffer 12 falls, the oscillator frequency of the VCO 8 falls accordingly. Consequently, the frequency of the local oscillation signal fₒ fed back from the VCO 8 to the PC 3 falls, and the frequency of the comparison signal fᵥ obtained by dividing this frequency also falls. Then, the frequency of the comparison signal fᵥ which was higher than the frequency of the reference signal fᵣ becomes close to the frequency of the reference signal fᵣ. As a result, the frequency of a local oscillation signal fₒ outputted from the VCO 8 becomes close to a desired frequency proportional to the frequency of the reference signal fᵣ.

In actuality, a voltage value supplied through the D/A converter 6 from the up/down counter 5 and a voltage value supplied through the buffer 12 from the S/H circuit 11 are added by the adder 7 and the added voltage value is supplied to the VCO 8. In other words, a voltage value which undergoes a micro adjustment by the S/H circuit 11 is added to a voltage value which undergoes a rough adjustment by the up/down counter 5 and the oscillator frequency of the VCO 8 is controlled by the added voltage value.

Then, finally the phase of the comparison signal fᵥ is completely synchronized with the phase of the reference signal fᵣ and the oscillator frequency of the VCO 8 is locked to a fixed frequency. In a non-locked state, the voltage values V₁, V₂, V₃ . . . which are sample-held for each cycle of the comparison signal fᵥ assume different values; but in a locked state, these voltage values are fixed. In addition, the time intervals of the sampling pulse SP are also fixed.

As described in detail above, according to the first embodiment, the up/down counter 5 is used to form the first locked loop; and the S/H circuit 11 is used to form the second locked loop. And the first locked loop performs a rough adjustment on a local oscillation frequency; and the second locked loop performs a micro adjustment on a local oscillation frequency. As described above, a method is used to configure the frequency synthesizer using the up/down counter 5 and thus the method does not require an operation such as charging or pumping an electric charge to and from the capacitor depending on the phase difference between the reference signal fᵣ and the comparison signal fᵥ. Therefore, it is possible to omit an LPF using a large-capacity capacitor from the frequency synthesizer.

In addition, according to the first embodiment, it is not required to increase the number of bits of the up/down counter 5 in order to increase the control accuracy of a local oscillation frequency to be locked, the local oscillation frequency can be locked to a desired frequency at a high speed. Additionally, a micro adjustment using the S/H circuit 11 can lock the local oscillation frequency with a good precision. Accordingly, the frequency synthesizer can be configured to be integrated on a single semiconductor chip without sacrificing the control accuracy of the local oscillation frequency to be locked and the processing speed.

### Second Embodiment

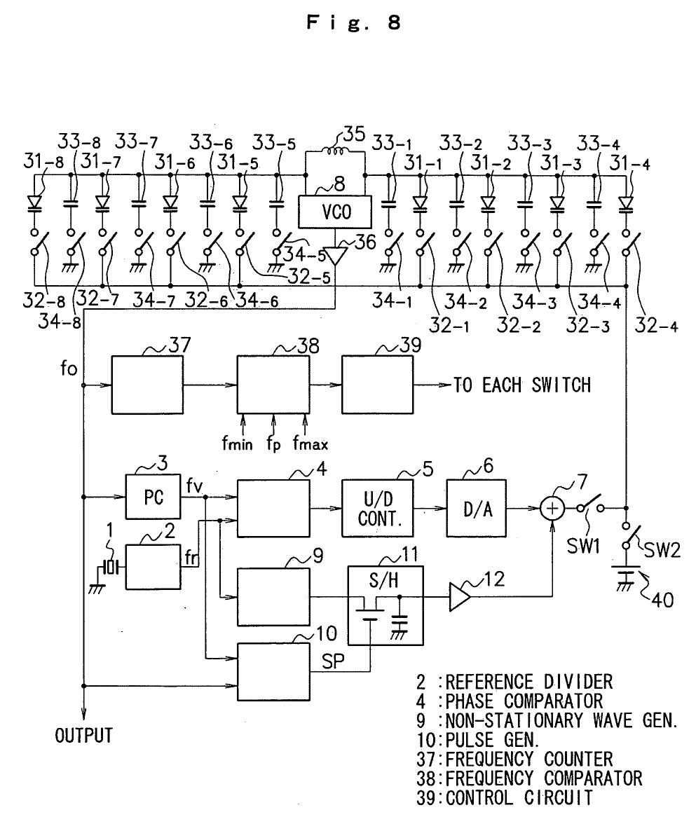

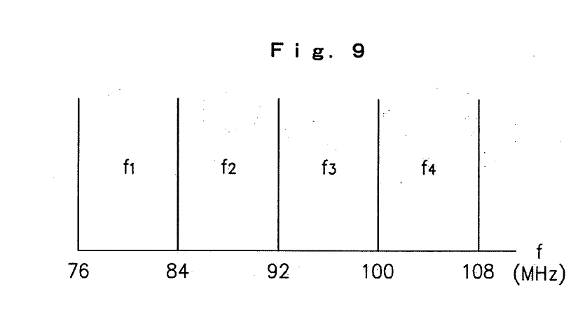

Hereinafter, a second embodiment of the present invention will be described. FIG. 8 shows an example of an overall configuration of a frequency synthesizer in accordance with the second embodiment. It should be noted that in FIG. 8, the same reference numerals as shown in FIG. 3 denote the elements having the same function, and a redundant description thereof is omitted. It should be noted that all the configuration elements shown in FIG. 8 are integrated on a single semiconductor chip, for example, by a CMOS process or a BiCMOS process. However, according to the present embodiment, all the configuration elements shown in FIG. 8 need not be integrated on a single semiconductor chip.

According to the second embodiment, the VCO 8 is connected to a plurality of varactor diodes 31₋₁ to 31₋₈ each having a different capacitance value; a plurality of switches 32₋₁ to 32₋₈ each for selecting one of the plurality of varactor diodes 31₋₁ to 31₋₈; a plurality of resonant capacitors 33₋₁ to 33₋₈ each having a different capacitance value; a plurality of switches 34₋₁ to 34₋₈ each for selecting one of the plurality of resonant capacitors 33₋₁ to 33₋₈; a resonant coil 35; and a buffer 36.

The plurality of varactor diodes 31₋₁ to 31₋₈ are connected from the plurality of switches 32₋₁ to 32₋₈ through the switch SW1 to the adder 7 as well as connected through the switch SW2 to a fixed voltage power supply 40. The switch SW1 and the switch SW2 are controlled by a control circuit 39 described later such that whenever a switch is on, the other switch is off. More specifically, when the switch SW1 is on, the switch SW2 is off; and when the switch SW2 is on, the switch SW1 is off.

The plurality of switches 32₋₁ to 32₋₈ are selectively turned on by the control of the control circuit 39. Here, a pair of the switch 32₋₁ and the switch 32₋₅, a pair of the switch 32₋₂ and the switch 32₋₆, a pair of the switch 32₋₃ and the switch 32₋₇, and a pair of the switch 32₋₄ and the switch 32₋₈ are turned on or off synchronously for each pair. Likewise, a pair of the switch 34₋₁ and the switch 34₋₅, a pair of the switch 34₋₂ and the switch 34₋₆, a pair of the switch 34₋₃ and the switch 34₋₇, and a pair of the switch 34₋₄ and the switch 34₋₈ which are connected between the plurality of resonant capacitors 33₋₁ to 33₋₈ and ground are turned on or off synchronously for each pair.

According to the second embodiment, the local oscillation frequency of the VCO 8 is configured to be changed by selecting any of the plurality of varactor diodes 31₋₁ to 31₋₈ each having a different capacitance value by any of the plurality of switches 32₋₁ to 32₋₈ as well as changing the capacitance value of the selected varactor diode by a voltage applied from the adder 7. More specifically, first, a rough adjustment is performed on the local oscillation frequency of the VCO 8 by selecting a varactor diode having an appropriate capacitance value of the plurality of varactor diodes 31₋₁ to 31₋₈. Afterward, a micro adjustment is performed on the local oscillation frequency of the VCO 8 by changing the capacitance value of the selected varactor diode by a voltage applied from the adder 7.

When any of the plurality of varactor diodes 31- to 31₋₈ is selected, the switch SW2 is turned on. When the switch SW2 is turned on, the voltage supplied through the switches 32₋₁ to 32₋₈ to the varactor diodes 31₋₁ to 31₋₈ becomes a fixed voltage of the power supply 40, but the capacitance value of a varactor diode connected to the VCO 8 can be variable by selectively turning on any of the switches 32₋₁ to 32₋₈. This changes the local oscillation frequency of the VCO 8.

After any of the plurality of varactor diodes 31₋₁ to 31₋₈ is selected, the switch SW1 is turned on. When the switch SW1 is on, a voltage outputted from the adder 7 is applied through the switches 32₋₁ to 32₋₈ to varactor diodes 31₋₁ to 31₋₈ in a reverse direction and the capacitor capacitance (junction capacitance) of the diode is changed. Here, except the locked time, a voltage value outputted from the adder 7 is changed. By the change of voltage, the capacitance values of varactor diodes 31₋₁ to 31₋₈ can be variable and the local oscillation frequency of the VCO 8 can be changed.

The second embodiment is provided with the following third locked loop in addition to the first locked loop using the up/down counter 5 and the second locked loop using the S/H circuit 11 as described in the first embodiment. The third locked loop is provided with a frequency counter 37, a frequency comparator 38, and a control circuit 39.

The frequency counter 37 counts the frequency of a local oscillation signal fₒ (hereinafter referred to as local oscillation frequency fₒ) outputted through the buffer 36 from the VCO 8. The frequency comparator 38 compares to see which is higher or lower between the local oscillation frequency fₒ counted by the frequency counter 37 and the target frequency fₚ to be finally converged by the frequency synthesizer, and supplies the compared result to the control circuit 39. Here, the target frequency fₚ is supplied from a not-shown microcomputer or a not-shown DSP (Digital Signal Processor) to the frequency comparator 38.

In addition, the frequency comparator 38 compares to see which is higher or lower between the frequencies fₘᵢₙ and fₘₐₓ each corresponding to the borders of a frequency range containing the target frequency fₚ of the frequency ranges obtained by dividing the range of oscillator frequencies permitted by the VCO 8 by “n” (2 or more integer) and the local oscillation frequency fₒ counted by the frequency counter 37 and supplies the compared result to the control circuit 39. Here, the frequencies fₘᵢₙ and fₘₐₓ each corresponding to the borders of a frequency range containing the target frequency fₚ are supplied from a not-shown microcomputer or a not-shown DSP to the frequency comparator 38.

For example, when the frequency synthesizer in accordance with the present embodiment is applied to an FM radio receiver, the FM receiving frequency range (76 to 108 MHz) is equally divided into four frequency ranges f₁ to f₄ as shown in FIG. 9. Here, assuming that the target frequency fₚ is 85 MHz, the frequency comparator 38 compares to see which is higher or lower between the local oscillation frequency fₒ and the target frequency fₚ (=85 MHz) and supplies the compared result to the control circuit 39. In addition, the frequency comparator 38 compares to see which is higher or lower between the frequencies fₘᵢₙ (=84 MHz) and fₘₐₓ (=92 MHz) each corresponding to the borders of the frequency range f₂ containing the target frequency fₚ and the local oscillation frequency fₒ and then supplies the compared result to the control circuit 39.

The control circuit 39 changes the selection states of the switches 32₋₁ to 32₋₈, the switches 34₋₁ to 34₋₈, SW1, and SW2 based on the compared result supplied from the frequency comparator 38. Initially, the control circuit 39 turns on the switch SW2 as well as, for example, turns on the switches 32₋₁, 32₋₅, 34₋₁, and 34₋₅ and turns off the other switches. This state is a state in which lowest frequency range f₁ is selected.

In this state, the frequency comparator 38 compares to see which is higher or lower between the local oscillation frequency fₒ and the target frequency fₚ (=85 MHz) as well as compares to see which is higher or lower between the frequencies fₘᵢₙ (=84 MHz) and fₘₐₓ (=92 MHz) each corresponding to the borders of the frequency range f₂ containing the target frequency fₚ and the local oscillation frequency fₒ and then supplies the compared result to the control circuit 39. Here, the control circuit 39 determines whether the condition fₘᵢₙ<fₒ<fₘₐₓ is satisfied. If the condition is not satisfied, the control circuit 39 changes the selection state of the switches 32₋₁ to 32₋₈ and the switches 34₋₁ to 34₋₈ depending on the compared relationship between the local oscillation frequency fₒ and the target frequency fₚ while the switch SW2 is turned on.

Here, the condition fₒ<fₚ is satisfied. Therefore, in order to increase the local oscillation frequency fₒ to be close to the target frequency fₚ, the switches 32₋₁, 32₋₅, 34₋₁, and 34₋₅ are changed to be turned off and the switches 32₋₂, 32₋₆, 34₋₂, and 34₋₆ are changed to be turned on. The state after this switching is a state in which the second frequency range f₂ is selected. As a result, the capacitance value of a varactor diode connected to the VCO 8 is greatly changed and the local oscillation frequency fₒ of the VCO 8 is greatly changed.

In this state, the frequency comparator 38 compares to see which is higher or lower between the local oscillation frequency fₒ and the target frequency fₚ as well as compares to see which is higher or lower between the frequencies fin and fₘₐₓ each corresponding to the borders of the frequency range f₂ containing the target frequency fₚ and the local oscillation frequency fₒ and then supplies the compared result to the control circuit 39. Here, the control circuit 39 determines whether the condition fₘᵢₙ<fₒ<fₘₐₓ is satisfied. Since the condition is satisfied here, the switch SW2 is turned off and the switch SW1 is turned on while the switches 32₋₂, 32₋₆, 34₋₂ and 34₋₆ are turned on. Thereby the varactor diodes 31₋₂ and 31₋₆ are in a selected state.

In a state where the switch SW1 is turned on and the varactor diodes 31₋₂ and 31₋₆ are selected, a voltage outputted from the adder 7 is applied through the switches SW1, 32₋₂ and 32₋₆ to the varactor diodes 31₋₂ and 31₋₆. Consequently, the capacitance values of the varactor diodes 31₋₂ and 31₋₆ are changed by a change of the voltage outputted from the adder 7, and the local oscillation frequency fₒ of the VCO 8 is gradually changed.

It should be noted that here the description is focused on an example starting with the lowest frequency range f₁ and proceeding to a higher frequency ranges f₂, f₃, and f₄ sequentially in that order, but this switching order is just an example. Note also that here, the FM receiving frequency range is equally divided into four frequency ranges f₁ to f₄, but dividing equally may not be required.

According to the frequency synthesizer in accordance with the second embodiment configured as above, the third locked loop using the frequency counter 37, the frequency comparator 38 and the control circuit 39 performs the roughest adjustment on a local oscillation frequency. More specifically, one of the equally divided four frequency ranges f₁ to f₄ is determined and any of the plurality of varactor diodes 311 to 31₋₈ is selected by the switches 32₋₁ to 32₋₈ so that the VCO 8 may oscillate within the determined frequency range.

In addition, the first locked loop using the up/down counter 5 performs a rough adjustment (finer adjustment than the adjustment by the third locked loop) on the local oscillation frequency fₒ by roughly changing the junction capacitance of the varactor diode selected by the third locked loop as well as the second locked loop using the S/H circuit 11 performs a micro adjustment on the local oscillation frequency fₒ by finely changing the junction capacitance of the varactor diode selected by the third locked loop.

As described in detail above, according to the second embodiment, a method is used to configure the frequency synthesizer using the up/down counter 5 and the frequency counter 37, and thus the method does not require an operation such as charging or pumping an electric charge to and from the capacitor depending on the phase difference between the reference signal fᵣ and the comparison signal fᵥ. Therefore, it is possible to omit an LPF using a large-capacity capacitor from the frequency synthesizer.

In addition, according to the second embodiment, it is not required to increase the number of bits of the counters 5 and 37 in order to increase the control accuracy of a local oscillation frequency to be locked, the local oscillation frequency can be locked to a desired frequency at a high speed. According to the second embodiment, the third locked loop determines a rough range of the local oscillation frequency and then the first locked loop performs a rough adjustment of the local oscillation frequency on the narrowed range. Accordingly, locking can be performed at a further higher speed than in the first embodiment. Moreover, the local oscillation frequency can be locked with a good precision by a micro adjustment by the second locked loop using the S/H circuit 11.

Accordingly, the frequency synthesizer can be configured to be integrated on a single semiconductor chip without sacrificing the control accuracy of the local oscillation frequency to be locked and the processing speed. In particular, according to the second embodiment, with respect to a frequency synthesizer of the type which performs an adjustment on a local oscillation frequency using a varactor diode, the frequency synthesizer containing the varactor diode can be configured to be integrated in a single semiconductor chip.

It should be noted that here, an example of equally dividing a frequency into four frequencies is described, but this is just an example. In the case where the number of divisions is one (no division), this case corresponds substantially to the first embodiment. Accordingly, the number of divisions is two or more, but it is preferable that the number of divisions should not be too large for the purpose of performing a rougher adjustment on the frequency in the third locked loop than in the first locked loop.

Moreover, an example of connecting a plurality of varactor diodes 31₋₁ to 31₋₈ each having a different capacitance value to the VCO 8 and selecting one pair of varactor diodes by the switches 32₋₁ to 32₋₈ is described, but the present invention is not limited to this. The capacitance values of the varactor diodes 31₋₁ to 31₋₈ may be the same. In this case, the total capacitance value of the varactor diodes connected to the VCO 8 can be variable not by selecting only one pair of varactor diodes by the switches 32₋₁ to 32₋₈ but by selecting one pair or a plurality of pairs of varactor diodes.

Likewise, with respect to the plurality of resonant capacitors 33₋₁ to 33₋₈ connected to the VCO 8, the capacitance values thereof is also the same, and the total capacitance value of the resonant capacitors connected to the VCO 8 can be variable by selecting one or more pairs of resonant capacitors. In so doing, the total capacitance value connected to the VCO 8 can be increased without increasing the capacitance value of an individual varactor diode or resonant capacitor and thereby it is possible to easily integrate on a semiconductor chip.

In addition, according to the first embodiment and the second embodiment, an example of the frequency synthesizer is described such that when a voltage supplied to the VCO 8 rises, an oscillator frequency of the VCO 8 rises, and when a voltage supplied to the VCO 8 falls, an oscillator frequency of the VCO 8 falls, but conversely, the present invention can be applied to a frequency synthesizer in which when a voltage supplied to the VCO 8 rises, an oscillator frequency of the VCO 8 falls and when a voltage supplied to the VCO 8 falls, an oscillator frequency of the VCO 8 rises.

In addition, the above first embodiment and the second embodiment are just an example of practicing the present invention and the technical scope of the present invention should not be restrictively construed by these embodiments. In other words, the present invention can be embodied in various forms without departing from the spirit or essential characteristics thereof.

### INDUSTRIAL APPLICABILITY

The present invention is applicable to a frequency synthesizer using a phase locked loop.

1. A frequency synthesizer, comprising:
a local oscillation circuit which outputs a local oscillation signal of a local oscillation frequency;
a variable frequency divider which divides the local oscillation signal outputted from said local oscillation circuit at a specified frequency dividing ratio;
a phase comparator which detects a phase difference between a comparison signal of a variable frequency outputted from said variable frequency divider and a reference signal of a reference frequency outputted from a reference generator and outputs a signal for oscillation control of said local oscillation circuit depending on the detected phase difference;
an up/down counter which performs a count operation based on said signal for oscillation control outputted from said phase comparator;
a D/A converter which obtains a voltage value by performing a D/A conversion on a count value outputted from said up/down counter and supplies said voltage value to said local oscillation circuit;
a non-stationary signal generating circuit which generates a non-stationary signal having a waveform in which a voltage value varies constantly in a fixed cycle in terms of time;
a pulse generation circuit which generates a sampling pulse based on said comparison signal outputted from said variable frequency divider; and
a sample hold circuit which sample-holds a voltage value of said non-stationary signal generated by said non-stationary signal generating circuit, by said sampling pulse generated by said pulse generation circuit and supplies the held voltage value to said local oscillation circuit.

2. The frequency synthesizer according to claim 1,
wherein said non-stationary signal generating circuit generates said non-stationary signal using said reference signal.

3. The frequency synthesizer according to claim 1,
wherein said pulse generation circuit generates said sampling pulse based on said comparison signal outputted from said variable frequency divider and said local oscillation signal outputted from said local oscillation circuit or a signal in mid flow of a frequency division by said variable frequency divider.

4. The frequency synthesizer according to claim 1,
wherein said local oscillation circuit being provided with a plurality of varactor diodes and a switch which selects any of said plurality of varactor diodes is configured such that said local oscillation frequency is changed by changing a capacitance value by selecting one or more of said plurality of varactor diodes,
said local oscillation circuit is comprising:
a frequency counter which counts a frequency of said local oscillation signal outputted from said local oscillation circuit;
a frequency comparator which compares to see which is higher or lower between a frequency of said local oscillation signal counted by said frequency counter and a target frequency as well as compares to see which is higher or lower between frequencies corresponding to the borders of a frequency range containing said target frequency of the frequency ranges obtained by dividing the range of oscillator frequencies permitted by said local oscillation circuit by “n” (2 or more integer) and a frequency of said local oscillation signal counted by said frequency counter; and
a control circuit which changes a selection state of said switch based on a result of comparison by said frequency comparator.
